(19) United States
(12) Patent Application Publication
(10) Pub. No.: US 2012/0002485 A1
(43) Pub. Date: Jan. 5, 2012

(54) SEMICONDUCTOR MEMORY DEVICE

(75) Inventors: Hitoshi Suwa, Osaka (JP); Takafumi Maruyama, Osaka (JP); Takashi Ono, Osaka (JP); Tadashi Nitta, Kyoto (JP); Kazuyo Nishikawa, Osaka (JP); Masahiro Ueminami, Kyoto (JP)

(73) Assignee: PANASONIC CORPORATION, Osaka (JP)

(21) Appl. No.: 13/233,789

(22) Filed: Sep. 15, 2011

Related U.S. Application Data
(63) Continuation of application No. PCT/JP2009/005886, filed on Nov. 5, 2009.

(30) Foreign Application Priority Data
May 19, 2009 (JP) 2009-120641

(51) Int. Cl. G11C 16/10; G11C 16/14

(52) U.S. Cl. 365/185.29; 365/185.18

(57) ABSTRACT

In a semiconductor memory circuit, a write voltage generation circuit receives an output voltage of a voltage boosting circuit to generate a write voltage to a memory cell. When the write voltage is low, a number-of-bits adjustment circuit increases the number of write bits of memory cells before write operation is performed. On the other hand, when the write voltage to a memory cell is high, the number-of-bits adjustment circuit decreases the number of write bits of memory cells before write operation is performed. The area and write time of the voltage boosting circuit can be reduced while the current supply capability of the voltage boosting circuit is efficiently used.

### CROSS-REFERENCE TO RELATED APPLICATIONS

This is a continuation of PCT International Application PCT/JP2009/005886 filed on Nov. 5, 2009, which claims priority to Japanese Patent Application No. 2009-120641 filed on May 19, 2009. The disclosures of these applications including the specifications, the drawings, and the claims are hereby incorporated by reference in their entirety.

### BACKGROUND

The present disclosure relates to semiconductor memory devices which include electrically writable and erasable memory cells and use a voltage obtained by boosting a power supply voltage during write and erase operations.

Conventionally, non-volatile memory, such as flash memory, EEPROM, etc., employs a floating-gate memory cell including an electrical conductor, such as polysilicon etc., which is used to store data. In recent years, particular attention has been paid to a nitride read-only memory (NROM) memory cell including an insulating ONO film (a composite structure of a nitride film and an oxide film) which is used to store data, in order to improve integration density and reliability.

A technique of changing a drain voltage in a stepwise manner has been proposed in order to efficiently write an NROM memory cell (see, for example, Japanese Translation of PCT International Application No. 2004-503040).

A technique of monitoring a boosted output voltage, and when the output voltage decreases, reducing the number of write bits, has been proposed in order to reduce a write failure which occurs when a power supply voltage decreases (see, for example, Japanese Patent No. 4124692).

As described in Japanese Translation of PCT International Application No. 2004-503040, in write operation of a semiconductor memory device, when a memory cell is written by changing the drain voltage in a stepwise manner, then if the power supply voltage is lower than the drain voltage, it is necessary to provide a voltage boosting circuit in a chip to supply the drain voltage. Therefore, when it is desired to reduce the write time by increasing the number of bits which are simultaneously written, the capability of the voltage boosting circuit needs to be enhanced, disadvantageously leading to an increase in chip area.

If the number of write bits is limited in order to reduce the chip area, then when the capability of the voltage boosting circuit is lower than a certain drain voltage, the capability of the voltage boosting circuit is not sufficiently exhibited, disadvantageously leading to an increase in write time.

In the configuration of Japanese Patent No. 4124692, it is necessary to provide a voltage detection circuit which detects a voltage to change the number of bits, disadvantageously leading to an increase in chip area.

### SUMMARY

The present disclosure describes implementations of a semiconductor memory device which includes a voltage boosting circuit and has reduced write and erase times and a reduced chip area.

The present inventor has paid attention to the following finding. There is a correspondence relationship between the output voltage of the voltage boosting circuit which is used as a data write or erase voltage to a memory region, such as a memory cell etc., and the current supply capability of the voltage boosting circuit. Specifically, when the output voltage of the voltage boosting circuit to the memory region is low, the current supply capability of the voltage boosting circuit is sufficient. As the output voltage of the voltage boosting circuit to the memory region increases, the current supply capability of the voltage boosting circuit decreases. Therefore, when data is written to the memory region, the number of write bits is changed based on the value of the write voltage, and when data is erased in the memory region, an erase unit is changed based on the value of the erase voltage. As a result, the write and erase times can be reduced while the current supply capability of the voltage boosting circuit is sufficiently exhibited.

An example semiconductor memory device according to the present disclosure includes a memory region including a plurality of memory elements, a write voltage generation circuit configured to generate a data write voltage to the memory element of the memory region based on a voltage adjustment signal for adjusting the data write voltage, and apply and supply the data write voltage to the memory region, a voltage boosting circuit configured to boost a power supply voltage to supply a required voltage to the write voltage generation circuit, and a number-of-bits adjustment circuit configured to change the number of write bits in the memory region based on the voltage adjustment signal.

In the semiconductor memory device, the voltage adjustment signal may be set to any one of two or more predetermined voltage values. If the voltage adjustment signal is set to a higher voltage value, the number-of-bits adjustment circuit may decrease the number of write bits, and if the voltage adjustment signal is set to a lower voltage value, the number-of-bits adjustment circuit may increase the number of write bits.

Thus, according to the present disclosure, the number-of-bits adjustment circuit is provided to optimize the number of write bits based on the voltage adjustment signal for determining the output voltage of the write voltage generation circuit. Therefore, when the output voltage is set to be low based on the voltage adjustment signal, the number of write bits can be increased, whereby the capability of the voltage boosting circuit can be used to the maximum extent possible.

Another example semiconductor memory device according to the present disclosure includes a memory region including a plurality of memory elements, a write voltage generation circuit configured to generate a data write voltage to the memory element of the memory region based on a voltage adjustment signal for adjusting the data write voltage, and apply and supply the data write voltage to the memory region, a voltage boosting circuit configured to boost a power supply voltage to supply a required voltage to the write voltage generation circuit, a pulse counting circuit configured to count the number of times of application of the data write voltage by the write voltage generation circuit, and a number-of-bits adjustment circuit configured to change the number of write bits in the memory region based on the count number of the pulse counting circuit.

In the semiconductor memory device, the write voltage may be increased every time the write voltage is applied. The number-of-bits adjustment circuit, when the pulse count number counted by the pulse counting circuit becomes greater than or equal to a predetermined pulse count number, may decrease the number of write bits. Thus, according to the present disclosure, when the drain voltage is increased every time the write voltage is applied, the number of write bits can be optimized in association with the write pulse count value, whereby the capability of the voltage boosting circuit can be used to the maximum extent possible.

Another example semiconductor memory device according to the present disclosure includes a memory region including a plurality of memory elements, an erase voltage generation circuit configured to generate a data erase voltage to the memory element of the memory region based on a voltage adjustment signal for adjusting the data erase voltage, and apply and supply the data erase voltage to the memory region, a voltage boosting circuit configured to boost a power supply voltage to supply a required voltage to the erase voltage generation circuit, and an erase unit adjustment circuit configured to change an erase unit of the memory region based on the voltage adjustment signal.

In the semiconductor memory device, the voltage adjustment signal may be set to any one of two or more predetermined voltage values. If the voltage adjustment signal is set to a higher voltage value, the erase unit adjustment circuit may decrease the erase unit, and if the voltage adjustment signal is set to a lower voltage value, the erasure unit adjustment circuit may increase the erase unit.

Thus, according to the present disclosure, the erase unit adjustment circuit is provided to optimize the erase unit of the memory region based on the voltage adjustment signal for determining the output voltage of the erase voltage generation circuit. Therefore, by increasing the erase unit when the output voltage of the erase voltage generation circuit is set to be low based on the voltage adjustment signal, whereby the capability of the voltage boosting circuit can be used to the maximum extent possible.

Another semiconductor memory device according to the present disclosure includes a memory region including a plurality of memory elements, an erase voltage generation circuit configured to generate a data erase voltage to the memory element of the memory region based on a voltage adjustment signal for adjusting the data erase voltage, and apply and supply the data erase voltage to the memory region, a voltage boosting circuit configured to boost a power supply voltage to supply a required voltage to the erase voltage generation circuit, a pulse counting circuit configured to count the number of times of application of the data erase voltage by the erase voltage generation circuit, and an erase unit adjustment circuit configured to change an erase unit of the memory region based on the count number of the pulse counting circuit.

In the semiconductor memory device, the erase voltage may be increased every time the erase voltage is applied. The erase unit adjustment circuit, when the pulse count number counted by the pulse counting circuit becomes greater than or equal to a predetermined pulse count number, may decrease the erase unit.

Thus, according to the present disclosure, when the drain voltage is increased every time an erase pulse is applied, the erase unit can be optimized in association with the erase pulse count value, whereby the capability of the voltage boosting circuit can be used to the maximum extent possible.

As described above, according to the present disclosure, the number-of-bits adjustment circuit is provided to optimize the number of write bits based on the voltage adjustment signal for determining the output voltage of the write voltage generation circuit. Therefore, when the output voltage is set to be low based on the voltage adjustment signal, the number of write bits can be increased, whereby the capability of the voltage boosting circuit can be used to the maximum extent possible. Therefore, by increasing the number of write bits when the write voltage is low, the write time can be reduced. Also, the voltage boosting capability can be optimized based on the tradeoff between the voltage boosting capability and the required speed, whereby the area of the voltage boosting circuit can be reduced.

According to the present disclosure, when the write voltage is increased every time the write voltage is applied, the number of write bits can be optimized based on the write pulse count value, whereby the capability of the voltage boosting circuit can be used to the maximum extent possible based on the write pulse count value. Therefore, advantages similar to those described above are obtained.

According to the present disclosure, the erase unit adjustment circuit is provided to optimize the erase unit of the memory region based on the voltage adjustment signal for determining the output voltage of the erase voltage generation circuit. Therefore, by increasing the erase unit when the output voltage of the voltage boosting circuit is set to be low based on the voltage adjustment signal, whereby the capability of the voltage boosting circuit can be used to the maximum extent possible. Therefore, when the erase voltage is low, the erase time can be reduced by increasing the erase unit. Also, the voltage boosting capability can be optimized based on the tradeoff between the voltage boosting capability and the required speed, whereby the area of the voltage boosting circuit can be reduced.

According to the present disclosure, when the erase voltage is increased every time the erase voltage is applied, the erase unit of the memory region can be optimized based on the erase pulse count value, whereby the capability of the voltage boosting circuit can be used to the maximum extent possible based on the erase pulse count value. Therefore, advantages similar to those described above are obtained.

### BRIEF DESCRIPTION OF THE DRAWINGS

FIG. 1 is a block diagram showing a configuration of a semiconductor memory device according to a first embodiment of the present disclosure.

FIG. 2 is a block diagram showing a configuration of a semiconductor memory device according to a second embodiment of the present disclosure.

FIG. 3 is a block diagram showing a configuration of a semiconductor memory device according to a third embodiment of the present disclosure.

FIG. 4 is a block diagram showing a configuration of a semiconductor memory device according to a fourth embodiment of the present disclosure.

FIG. 5 is a flowchart showing write operation of the semiconductor memory device of the first embodiment.

FIG. 6 is a timing chart showing the write operation of the semiconductor memory device of the first embodiment.

FIG. 7 is a flowchart showing write operation of the semiconductor memory device of the second embodiment.

FIG. 8 is a flowchart showing erase operation of the semiconductor memory device of the third embodiment.

FIG. 9 is a timing chart showing the erase operation of the semiconductor memory device of the third embodiment.

FIG. 10 is a flowchart showing write operation of the semiconductor memory device of the fourth embodiment.

FIG. 11 is a diagram showing the relationship between the current supply capability and output voltage of a voltage boosting circuit.

### DETAILED DESCRIPTION

Firstly, a semiconductor memory device according to the present disclosure will be roughly described. In the semiconductor memory device, memory cells are written and erased by using an output voltage of a voltage boosting circuit, and the level of current consumption is changed based on the output voltage of the voltage boosting circuit.

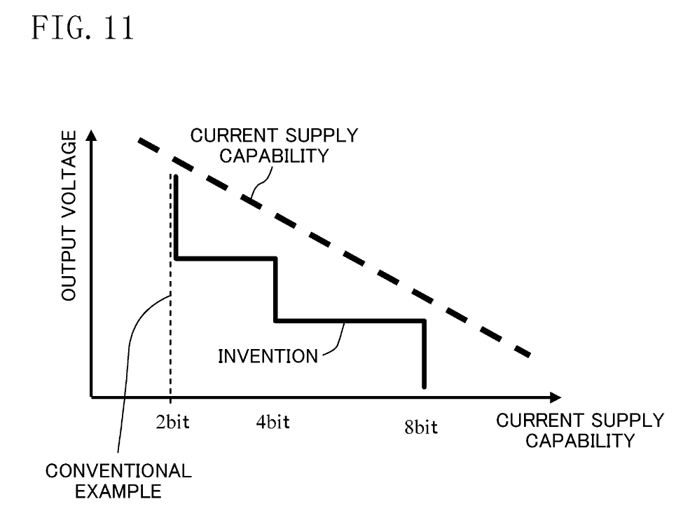

FIG. 11 shows the relationship between the current supply capability and output voltage of the voltage boosting circuit. As indicated by a dashed line in FIG. 11 where the horizontal axis indicates the current supply capability and the vertical axis indicates the output voltage, typically, when the output voltage is low, the voltage boosting circuit has a current supply capability, and as the output voltage increases, the current supply capability decreases. A solid line in FIG. 11 indicates the relationship between an output voltage of a write voltage generation circuit and the number of write bits in the present disclosure. A thin dashed line in FIG. 11 indicates the relationship between the output voltage and the number of write bits in the conventional art.

As can be seen from FIG. 11, conventionally, the number of write bits is constant regardless of the output voltage of the voltage boosting circuit. When the write voltage is set to be low, the voltage boosting circuit has a sufficient current supply capability, and therefore, in the present disclosure, an increased number of write bits are selected. On the other hand, when the write voltage is set to be high, the voltage boosting circuit has a low current supply capability, and therefore, a decreased number of write bits are selected. Thus, the number of write bits is adjusted, depending on the capability of the voltage boosting circuit. As a result, the write time can be reduced, and the area can be reduced by optimizing the voltage boosting circuit.

Embodiments of the present disclosure will be described hereinafter.

### First Embodiment

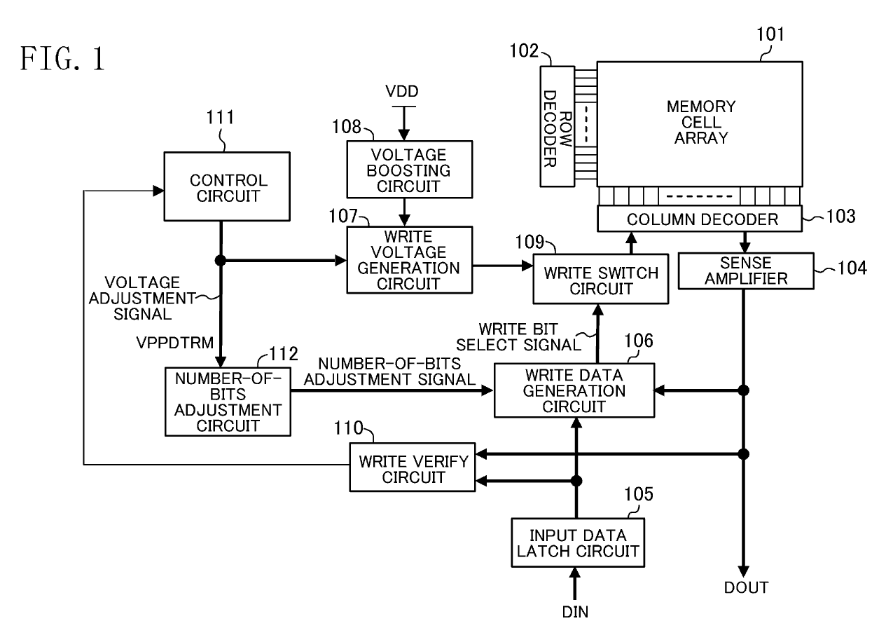

FIG. 1 is a block diagram showing a configuration of a semiconductor memory device according to a first embodiment of the present disclosure.

This semiconductor memory device includes a memory cell array (memory region) 101 including a plurality of non-volatile memory cells (memory elements), a row decoder 102 which selects any memory cell row, a column decoder 103 which selects any memory cell column, a plurality of sense amplifiers 104 each of which senses data of any memory cell selected by the row decoder 102 and the column decoder 103, an input data latch circuit 105 which latches external input write data, a write data generation circuit 106 which selects write bits from the write data in groups of write bits, the number of write bits in each group depending on a number-of-bits adjustment signal from a number-of-bits adjustment circuit 112 described below, and generates a write bit select signal, a write voltage generation circuit 107 which generates a write voltage based on a voltage adjustment signal from a control circuit 111 described below, and supplies the write voltage to a write switch circuit 109, a voltage boosting circuit 108 which boosts a power supply voltage VDD to supply a required voltage to the write voltage generation circuit 107, the write switch circuit 109 which applies and supplies the output voltage of the write voltage generation circuit 107 to a memory cell corresponding to the write bit select signal from the write data generation circuit 106, a write verify circuit 110 which compares data read from a memory cell with data DIN from the input data latch circuit 105 to determine whether or not there is a match in write data, the control circuit 111 which controls whether to perform the next write operation, based on the output result of the write verify circuit 110, and outputs a voltage adjustment signal for setting a write voltage required to write a memory cell, and the number-of-bits adjustment circuit 112 which changes the number of bits which are to be simultaneously written, based on the voltage adjustment signal of the control circuit 111.

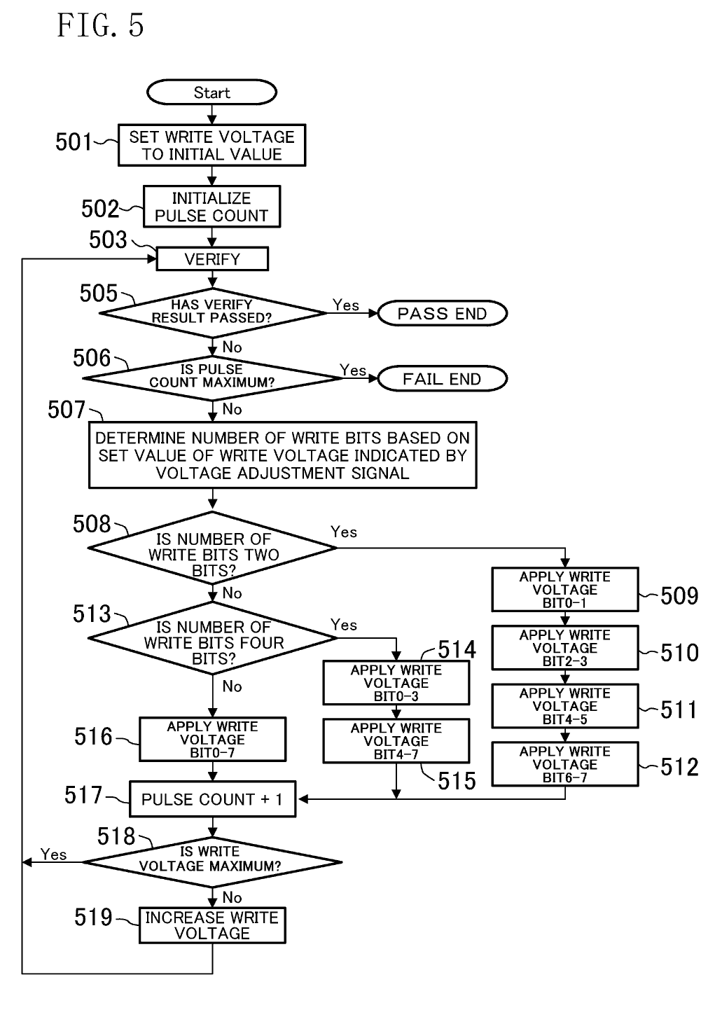

Next, operation of the semiconductor memory device of the first embodiment will be described with reference to a sequential flow diagram shown in FIG. 5.

For example, it is assumed that the length of write data is 8 bits and the write data is 00000000b (“b” indicates that the data is binary, “1” indicates the erased state, and “0” indicates the written state). After the start of write operation, initially, the write voltage adjustment signal is initialized (step 501), and the pulse count number is initialized (step 502). Thereafter, the write verify circuit 110 compares a write expected value input to and held by the input data latch circuit 105 with data read from a memory cell by a sense amplifier 104 to determine whether these values match each other (verify operation) (step 503).

Next, the result of the determination by the verify operation is checked (step 505). If there is a match, the write operation is ended (PASS END).

On the other hand, if the determination result indicates that there is not a match, it is next determined whether or not the number of times of write operation has reached the maximum value (step 506). If the number of times of write operation has reached the maximum value, the write operation is ended (FAIL END).

If the number of times of write operation has not reached the maximum value, the number of write bits is next determined by the number-of-bits adjustment circuit 112 based on the set value of the write voltage adjustment signal from the control circuit 111 (step 507).

Next, it is determined whether or not the number of bits determined by the number-of-bits adjustment circuit 112 is two bits (step 508). If the number of bits is two bits, the first two bits (BIT0 and BIT1) of the write data are written (step 509), then the next two bits (BIT2 and BIT3) are written (step 510), then the next two bits (BIT4 and BIT5) are written (step 511), and then the next two bits (BIT6 and BIT7) are written (step 512).

It is also determined whether or not the number of bits determined by the number-of-bits adjustment circuit 112 is four bits (step 513). If the number of bits determined by the number-of-bits adjustment circuit 112 is four bits, the first four bits (BIT0-BIT3) of the write data are written (step 514), and then the next four bits (BIT4-BIT7) are written (step 515).

If the number of bits determined by the number-of-bits adjustment circuit 112 is not four bits, all eight bits (BIT0-BIT7) of the write data are written (step 516). Thereafter, the pulse count is incremented by one (step 517), and it is determined whether or not the set value of the write voltage is the maximum value (step 518). If the write voltage has the maximum value, control returns to the verify operation. If the write voltage does not have the maximum value, the write voltage adjustment signal is changed to increase the write voltage (step 519), and thereafter, control returns to the verify operation, and the above write operation is repeatedly performed until the input data matches the read data.

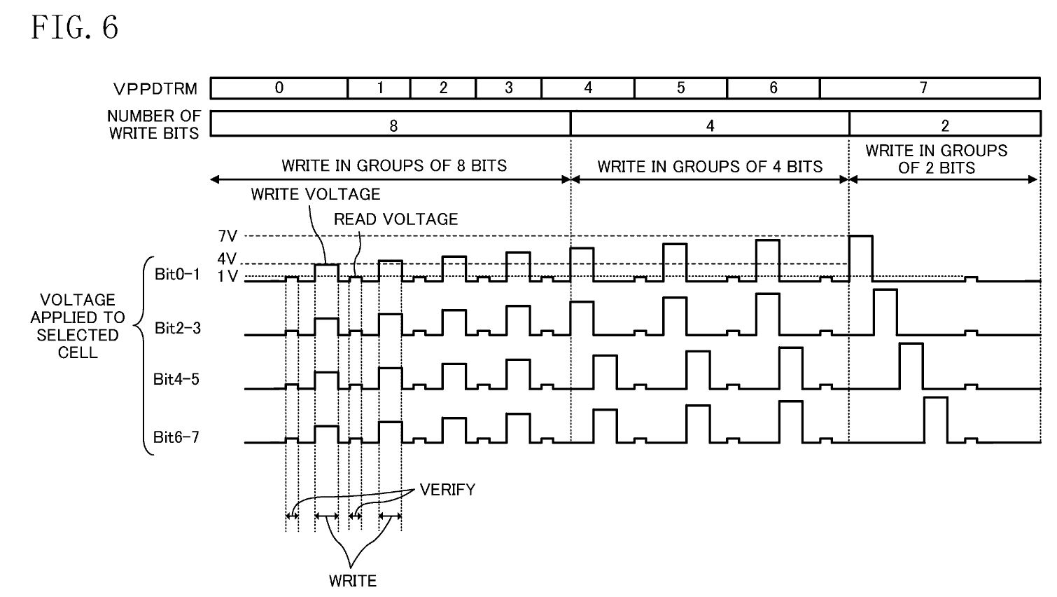

As shown in a timing chart of FIG. 6, the number of bits to be simultaneously written is changed based on the set value of the write voltage adjustment signal (VPPDTRM) from the control circuit 111. In steps 509-512, 514, 515, and 517 (write voltage application step), write data is divided into portions each including the predetermined number of write bits before being applied to the drains of selected memory cells.

After the write voltage is applied to all bits to be written, the write voltage adjustment signal (VPPDTRM) is changed to increase the set value of the write voltage.

Thus, by changing the number of write bits based on the output voltage of the write voltage generation circuit 107, the capability of the voltage boosting circuit 108 can be used to the maximum extent possible even when the write voltage is low, whereby the write time can be reduced.

### Second Embodiment

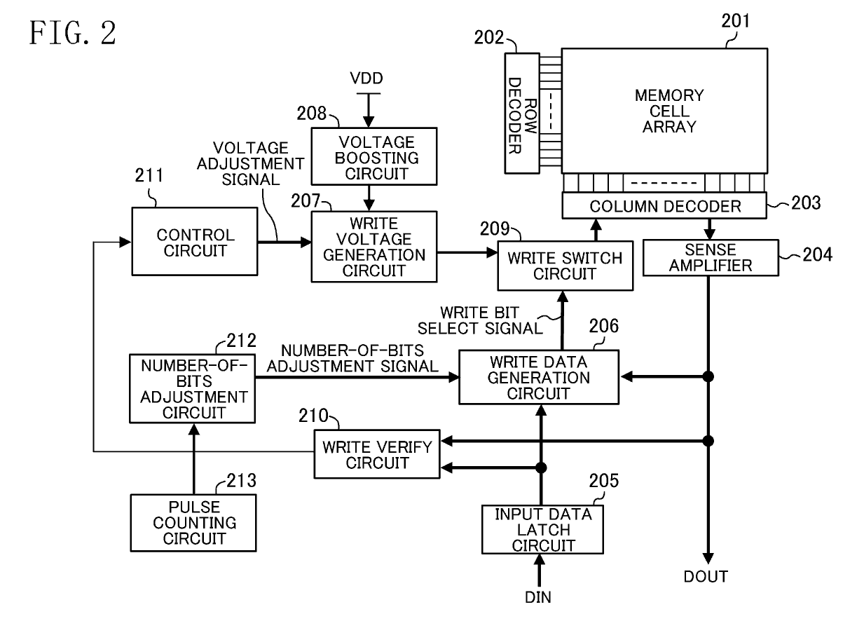

FIG. 2 is a block diagram showing a configuration of a semiconductor memory device according to a second embodiment of the present disclosure.

This semiconductor memory device includes a memory cell array 201 including a plurality of non-volatile memory cells, a row decoder 202 which selects any memory cell row, a column decoder 203 which selects any memory cell column, a plurality of sense amplifiers 204 each of which senses data of any memory cell selected by the row decoder 202 and the column decoder 203, an input data latch circuit 205 which latches external input write data, a write data generation circuit 206 which selects write bits from the write data in groups of write bits, the number of write bits in each group depending on a number-of-bits adjustment signal from a number-of-bits adjustment circuit 212 described below, and generates a write bit select signal, a write voltage generation circuit 207 which generates a write voltage based on a voltage adjustment signal from a control circuit 211 described below, and supplies the write voltage to a write switch circuit 209, a voltage boosting circuit 208 which boosts a power supply voltage to supply a required voltage to the write voltage generation circuit 207, the write switch circuit 209 which applies and supplies the output voltage of the write voltage generation circuit 207 to memory cells corresponding to the write bit select signal from the write data generation circuit 206, a write verify circuit 210 which compares data read from a sense amplifier 204 with data from the input data latch circuit 205 to determine whether or not there is a match in write data, the control circuit 211 which controls whether to perform the next write operation, based on the output result of the write verify circuit 210, and outputs a voltage adjustment signal for setting a write voltage required to write a memory cell, a pulse counting circuit 213 which counts the number of times of application of the write voltage to a memory cell by the write switch circuit 209, and the number-of-bits adjustment circuit 212 which changes the number of bits to be simultaneously written, based on the count number of the pulse counting circuit 213. The number-of-bits adjustment circuit 212 decreases the number of bits to be simultaneously written in response to an increase in the count number of the pulse counting circuit 213. For example, when the count number of the pulse counting circuit 213 becomes greater than or equal to a predetermined count number, the number-of-bits adjustment circuit 212 decreases the number of bits to be simultaneously written.

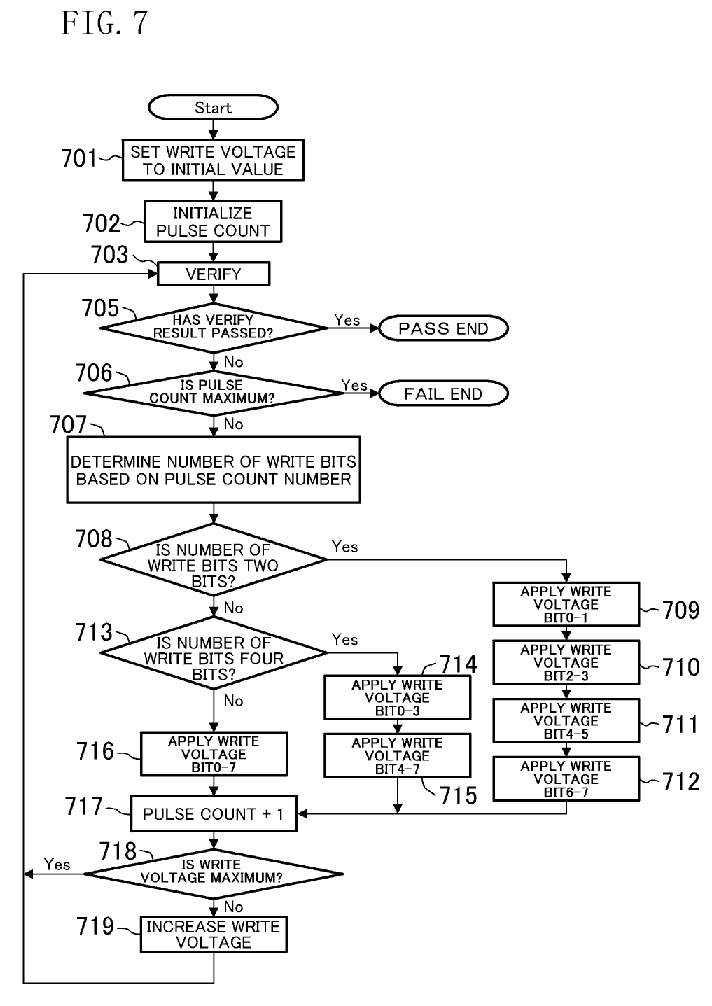

Next, operation of the semiconductor memory device of the second embodiment will be described with reference to a sequential flow diagram shown in FIG. 7.

In FIG. 2, in step 707, the number of write bits is determined based on a write pulse count number. This embodiment is different from the first embodiment in that the number of write bits is changed based on the count number of the pulse counting circuit 213 instead of the write voltage adjustment signal VPPDTRM of the first embodiment.

The other operation is similar to that of the first embodiment, and steps 701-719 of FIG. 7 correspond to steps 501-519 of FIG. 5 and therefore will not be described.

With the configuration of this embodiment, the number of write bits can be changed based on a write voltage which is changed as the pulse count number increases, and therefore, advantages similar to those of the first embodiment are obtained.

### Third Embodiment

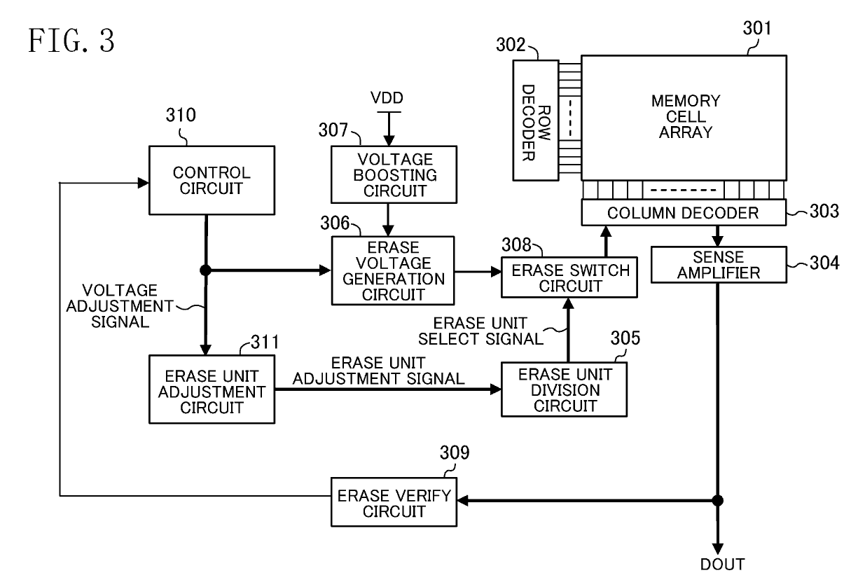

FIG. 3 is a block diagram showing a configuration of a semiconductor memory device according to a third embodiment of the present disclosure.

This semiconductor memory device includes a memory cell array 301 including a plurality of memory cell blocks each including a plurality of non-volatile memory cells, a row decoder 302 which selects any memory cell row, a column decoder 303 which selects any memory cell column, a plurality of sense amplifiers 304 which are connected to the respective corresponding memory cell blocks and each of which senses data of any memory cell selected by the row decoder 302 and the column decoder 303, an erase unit division circuit 305 which divides the memory cell array 301 into erase units the number of which is specified by an erase unit adjustment signal from an erase unit adjustment circuit 311 described below, an erase voltage generation circuit 306 which generates an erase voltage based on a voltage adjustment signal from a control circuit 310 described below, and supplies the erase voltage to an erase switch circuit 308, a voltage boosting circuit 307 which boosts a power supply voltage VDD to supply a required voltage to the erase voltage generation circuit 306, the erase switch circuit 308 which supplies the output voltage of the erase voltage generation circuit 306 to memory cells corresponding to the erase unit obtained by the erase unit division circuit 305, an erase verify circuit 309 which confirms that data read from a sense amplifier 304 is in the erased state to determine whether or not erase operation has been completed, the control circuit 310 which controls whether to perform the next erase operation, based on the output result of the erase verify circuit 309, and outputs a voltage adjustment signal for setting a voltage required to erase memory cells, and the erase unit adjustment circuit 311 which adjusts the erase unit of the memory cell array 301 in which memory cells are simultaneously erased, based on the erase voltage adjustment signal.

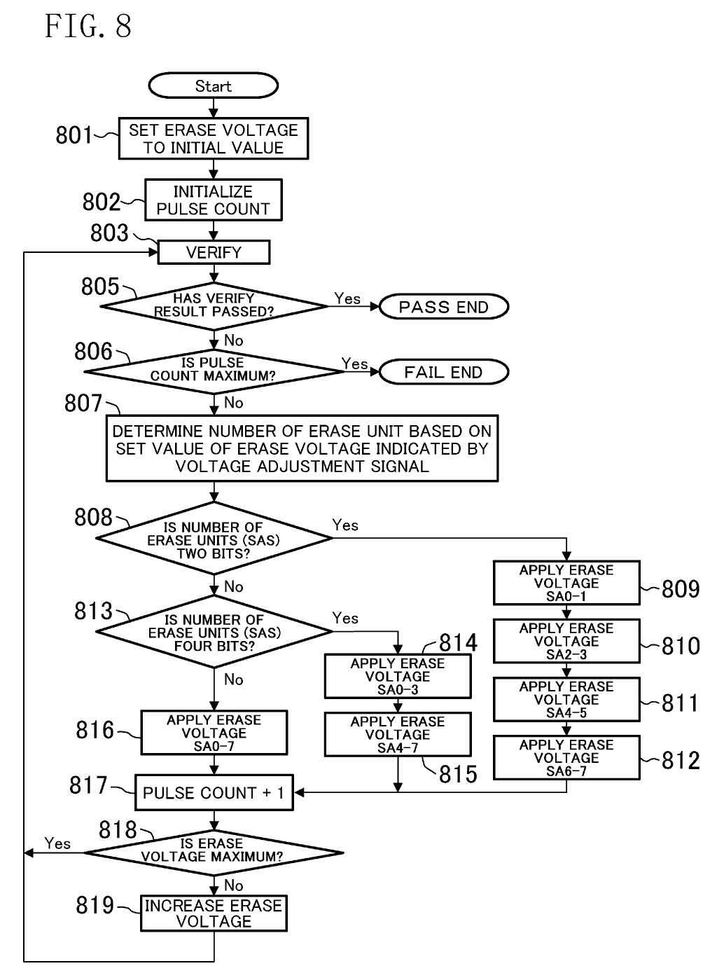

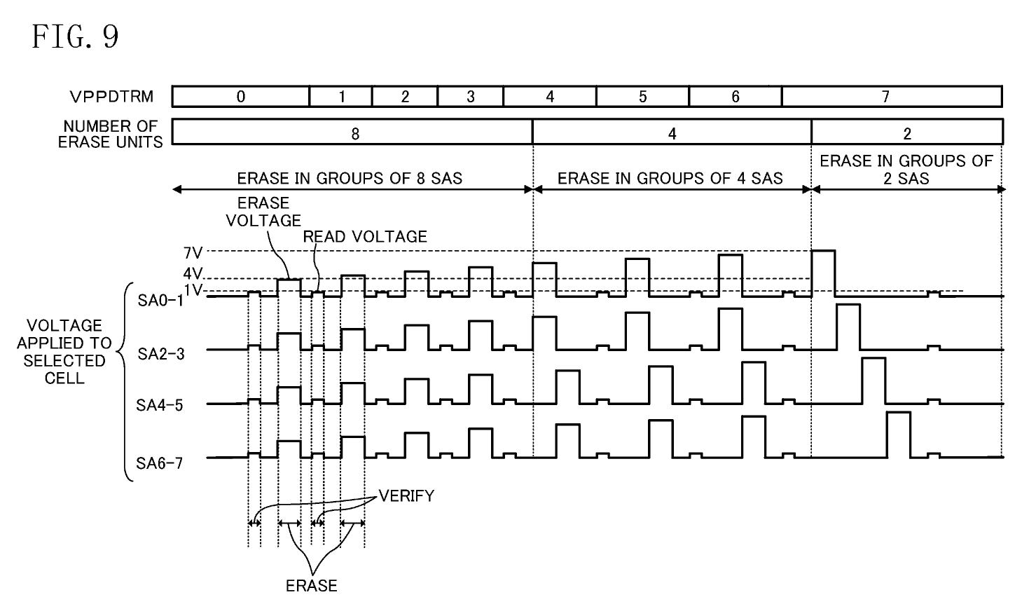

Next, operation of the semiconductor memory device of this embodiment will be described with reference to a sequential flow diagram shown in FIG. 8 and a timing chart shown in FIG. 9.

After the start of erase operation, initially, the erase voltage adjustment signal is initialized (step 801), and the pulse count number is initialized (step 802). Thereafter, the erase verify circuit 309 performs verify operation to determine whether or not data of a sense amplifier 304 read from memory cells has been erased (step 803).

Next, the result of the determination by the verify operation is checked (step 805). When the data has been erased, the erase operation is ended (PASS END).

On the other hand, the determination result shows that the data has not been erased, it is next determined whether or not the number of times of erase operation has reached the limit (step 806). If the number of times of erase operation has reached the limit, the erase operation is also ended (FAIL END).

If the number of times of erase operation has not reached the limit, the erase unit adjustment circuit 311 next determines an erase unit based on the set value of the erase voltage adjustment signal (step 807).

Next, the erase unit division circuit 305 determines whether or not the number of erase units (SAs) determined by the erase unit adjustment circuit 311 is two (step 808). If the number of erase units is two, the first two (SA0 and SA01) of the erase units are erased (step 809), then the next two erase units (SA2 and SA3) are erased (step 810), then the next two erase units (SA4 and SA5) are erased (step 811), and then the next two erase units (SA6 and SA7) are erased (step 812).

The erase unit division circuit 305 determines whether or not the number of erase units determined by the erase unit adjustment circuit 311 is four (step 813). If the number of erase units is four, the first four (SA0-SA3) of the erase units are erased (step 814), and then the next erase units (SA4-SA7) are erased (step 815).

If the number of erase units determined by the erase unit adjustment circuit 311 is not four, all eight of the erase units (SA0-SA7) are erased (step 816).

Thereafter, the pulse count is incremented by one (step 817). It is determined whether or not the set value of the erase voltage is the maximum value (step 818). If the erase voltage has the maximum value, control returns to the verify operation. If the erase voltage has not the maximum value, the erase voltage adjustment signal is changed to increase the erase voltage (step 819), and thereafter, control returns to the verify operation. The erase operation is repeatedly performed until the input data matches the read data.

As shown in the timing chart of FIG. 9, the number of erase units to be simultaneously selected is changed based on the set value of the erase voltage adjustment signal VPPDTRM. In steps 809-812, 814, 815, and 817 (erase voltage application step), the memory cell array 301 is divided into erase units, and an erase voltage is applied to the drains of selected memory cells.

After the erase voltage is applied to the entire erase unit region, the voltage adjustment signal VPPDTRM is changed to increase the set value of the erase voltage.

Thus, by changing the number of erase units based on the output voltage of the erase voltage generation circuit 306, the capability of the voltage boosting circuit 307 can be used to the maximum extent possible even when the erase voltage is low, whereby the erase time can be reduced.

### Fourth Embodiment

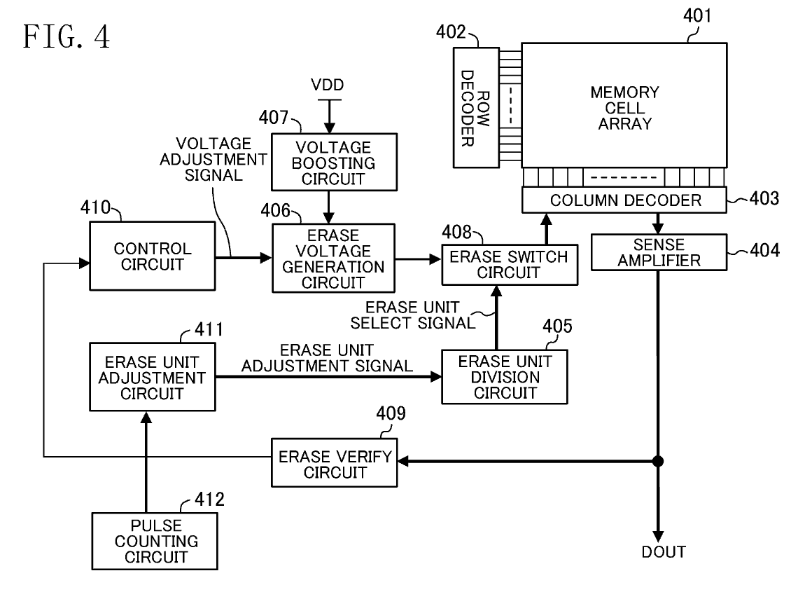

FIG. 4 is a block diagram showing a configuration of a semiconductor memory device according to a fourth embodiment of the present disclosure.

This semiconductor memory device includes a memory cell array 401 including a plurality of memory cell blocks each including a plurality of non-volatile memory cells, a row decoder 402 which selects any memory cell row, a column decoder 403 which selects any memory cell column, a plurality of sense amplifiers 404 which are connected to the respective corresponding memory cell blocks and each of which senses data of any memory cell selected by the row decoder 402 and the column decoder 403, an erase unit division circuit 405 which divides the memory cell array 401 into erase units the number of which is specified by an erase unit adjustment signal from an erase unit adjustment circuit 411 described below, an erase voltage generation circuit 406 which generates an erase voltage based on a voltage adjustment signal from a control circuit 410 described below, and supplies the erase voltage to an erase switch circuit 408, a voltage boosting circuit 407 which boosts a power supply voltage VDD to supply a required voltage to the erase voltage generation circuit 406, the erase switch circuit 408 which applies and supplies the output voltage of the erase voltage generation circuit 406 to memory cells corresponding to the erase unit obtained by the erase unit division circuit 405, an erase verify circuit 409 which confirms that data read from a sense amplifier 404 is in the erased state to determine whether or not erase operation has been completed, the control circuit 410 which controls whether to perform the next erase operation, based on the output result of the erase verify circuit 409, and outputs an erase voltage adjustment signal for setting a voltage required to erase memory cells, a pulse counting circuit 412 which counts the number of times of application of the erase voltage by the erase switch circuit 408, and the erase unit adjustment circuit 411 which adjusts the erase unit in which memory cells are simultaneously erased, based on the count number of the pulse counting circuit 412.

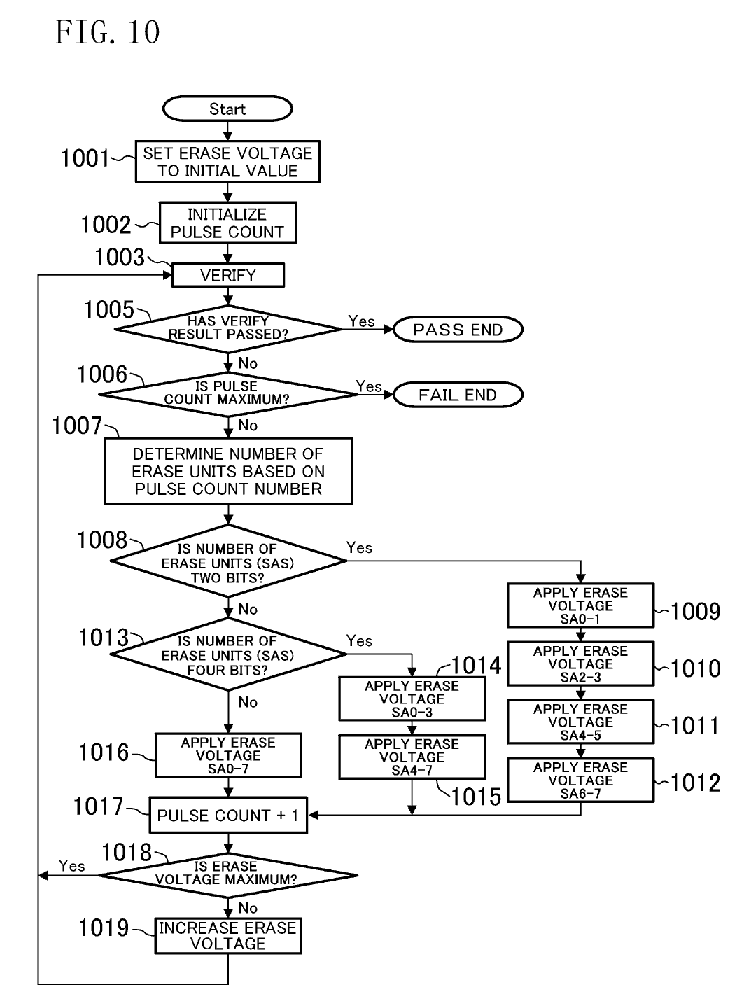

Next, operation of the semiconductor memory device of the fourth embodiment will be described with reference to FIG. 10.

In FIG. 4, the fourth embodiment is similar to the third embodiment, except that, in step 1007, the erase unit is changed based on the pulse count number of the pulse count circuit 412 instead of the voltage adjustment signal of the third embodiment. Steps 1001-1019 of FIG. 10 correspond to steps 801-819 of FIG. 8 and therefore will not be described.

With the configuration of the fourth embodiment, the erase unit can be changed based on the erase voltage which is changed as the pulse count number increases. Therefore, advantages similar to those of the third embodiment are obtained.

Although an example in which the write and erase voltages are increased has been described in the above embodiments, the present disclosure is, of course, applicable to any semiconductor memory device that has a voltage boosting circuit and in which the level of current consumption can be changed with respect to an arbitrarily set voltage value.

As described above, the present disclosure is useful for the reduction of the chip area and the reduction of the write and erase times in a semiconductor memory device which has a voltage boosting circuit and in which a memory cell is written and erased using an output voltage of the voltage boosting circuit.

What is claimed is:

1. A semiconductor memory device comprising:
a memory region including a plurality of memory elements;
a write voltage generation circuit configured to generate a data write voltage to the memory element of the memory region based on a voltage adjustment signal for adjusting the data write voltage, and apply and supply the data write voltage to the memory region;
a voltage boosting circuit configured to boost a power supply voltage to supply a required voltage to the write voltage generation circuit; and
a number-of-bits adjustment circuit configured to change the number of write bits in the memory region based on the voltage adjustment signal.

2. The semiconductor memory device of claim 1, wherein
the voltage adjustment signal is set to any one of two or more predetermined voltage values, and
if the voltage adjustment signal is set to a higher voltage value, the number-of-bits adjustment circuit decreases the number of write bits, and if the voltage adjustment signal is set to a lower voltage value, the number-of-bits adjustment circuit increases the number of write bits.

3. A semiconductor memory device comprising:
a memory region including a plurality of memory elements;
a write voltage generation circuit configured to generate a data write voltage to the memory element of the memory region based on a voltage adjustment signal for adjusting the data write voltage, and apply and supply the data write voltage to the memory region;
a voltage boosting circuit configured to boost a power supply voltage to supply a required voltage to the write voltage generation circuit;
a pulse counting circuit configured to count the number of times of application of the data write voltage by the write voltage generation circuit; and
a number-of-bits adjustment circuit configured to change the number of write bits in the memory region based on the count number of the pulse counting circuit.

4. The semiconductor memory device of claim 3, wherein
the write voltage is increased every time the write voltage is applied, and
the number-of-bits adjustment circuit, when the pulse count number counted by the pulse counting circuit becomes greater than or equal to a predetermined pulse count number, decreases the number of write bits.

5. A semiconductor memory device comprising:
a memory region including a plurality of memory elements;
an erase voltage generation circuit configured to generate a data erase voltage to the memory element of the memory region based on a voltage adjustment signal for adjusting the data erase voltage, and apply and supply the data erase voltage to the memory region;
a voltage boosting circuit configured to boost a power supply voltage to supply a required voltage to the erase voltage generation circuit; and
an erase unit adjustment circuit configured to change an erase unit of the memory region based on the voltage adjustment signal.

6. The semiconductor memory device of claim 5, wherein
the voltage adjustment signal is set to any one of two or more predetermined voltage values, and
if the voltage adjustment signal is set to a higher voltage value, the erase unit adjustment circuit decreases the erase unit, and if the voltage adjustment signal is set to a lower voltage value, the erasure unit adjustment circuit increases the erase unit.

7. A semiconductor memory device comprising:
a memory region including a plurality of memory elements;
an erase voltage generation circuit configured to generate a data erase voltage to the memory element of the memory region based on a voltage adjustment signal for adjusting the data erase voltage, and apply and supply the data erase voltage to the memory region;
a voltage boosting circuit configured to boost a power supply voltage to supply a required voltage to the erase voltage generation circuit;
a pulse counting circuit configured to count the number of times of application of the data erase voltage by the erase voltage generation circuit; and
an erase unit adjustment circuit configured to change an erase unit of the memory region based on the count number of the pulse counting circuit.

8. The semiconductor memory device of claim 7, wherein
the erase voltage is increased every time the erase voltage is applied, and
the erase unit adjustment circuit, when the pulse count number counted by the pulse counting circuit becomes greater than or equal to a predetermined pulse count number, decreases the erase unit.
